(19) United States
(12) Patent Application Publication
(10) Pub. No.: US 2012/0280688 A1
(43) Pub. Date: Nov. 8, 2012

(54) Magnetic Resonance (MR) Radio Frequency (RF) Coil and/or High Resolution Nuclear Magnetic Resonance

(75) Inventor: C. Richard Hullihen, III, Cleveland, OH (US)

(73) Assignee: m2m Imaging Corp., Highland Heights, OH (US)

(21) Appl. No.: 13/462,923

(22) Filed: May 3, 2012

Related U.S. Application Data
(60) Provisional application No. 61/481,806, filed on May 3, 2011.

(51) Int. Cl. G01R 33/341

(52) U.S. Cl. 324/322

(57) ABSTRACT

An MR coil including an MR RF receive coil comprising graphene.

### RELATED APPLICATION

This is a utility application of U.S. provisional application Ser. No. 61/481,806, filed Sep. 3, 2012.

### TECHNICAL FIELD

The following generally relates to a magnetic resonance (MR) radio frequency (RF) coil for a magnetic resonance imaging (MRI) system, a nuclear magnetic resonance (NMR) spectroscopy system, and/or other MR system.

### BACKGROUND

NMR spectroscopy has been used to study molecular physics, crystals and non-crystalline materials, and MRI has been used to capture information about the internal structure and function of an object under examination. MR imaging techniques have been used in pre-clinical and clinical applications to provide information on the physiology of animal and/or human patients. Generally, for imaging, nuclei of an object are aligned in a magnetic field, the nuclei are then excited with an RF signal, magnetic resonance signals generated by the excited nuclei are sensed by an RF receive coil, and the sensed magnetic resonance signals are used to generate images of the object.

The image quality of the images depends on the signal to noise ratio (SNR), which must be at an acceptable level, of the sensed magnetic resonance signals. The sources of noise for an RF receive coil may originate either in the RF receive coil itself or in the sample being imaged. Typically, as the size of an RF receive coil increases, the noise in the RF receive coil increases in proportion to the length of the RF receive coil. Conventional RF receive coils have been made from copper and are operated at ambient temperature.

Coil noise in copper coils can be reduced by reducing the temperature of the coil. Coil noise can be further reduced by using a high temperature superconductor (HTS) material, which has a lower resistance than copper. Unfortunately, cooling such RF coils has included immersing the coils in a cold fluid bath such as liquid nitrogen or liquid helium, which boils off quickly, so frequent replacement of the fluid is necessary. A need exists for other approaches to further decrease noise and/or improve SNR and thus improve image quality.

### SUMMARY

Aspects of the present invention address these matters, and others.

According to one aspect, an MR coil includes an MR RF receive coil comprising graphene.

According to another aspect, an MRI imaging system includes a main magnet that generates a main magnetic field in an examination region, a gradient coil that generates a time varying gradient magnetic field along mutually orthogonal x, y, and/or z-axis, an RF transmit coil that produces radio frequency signals that excite magnetic resonance in magnetically active nuclei disposed in the examination region, and an RF receive coil that receives magnetic resonance signals generated by the magnetically active nuclei and generates an electrical signal indicative thereof, wherein the RF receive coil includes graphene.

According to another aspect, an NMR apparatus includes an MR coil comprising graphene.

According to another aspect, an MR device includes an MR coil formed from a material with a resistivity that is less than that of oxygen free copper and that does not vary much with temperature relative to HTS.

Other aspects, objects, features, and advantages of the present invention will become apparent with reference to the drawings and detailed description that follow.

### DRAWINGS

FIG. 1 schematically illustrates an example MR scanner.

### DESCRIPTION

The following relates to a magnetic resonance (MR) radio frequency (RF) coil for a magnetic resonance imaging (MRI) scanner, a nuclear magnetic resonance (NMR) spectroscopy system, and/or other MR system. However, for explanatory purposes, the following is described in the context of an MR scanner.

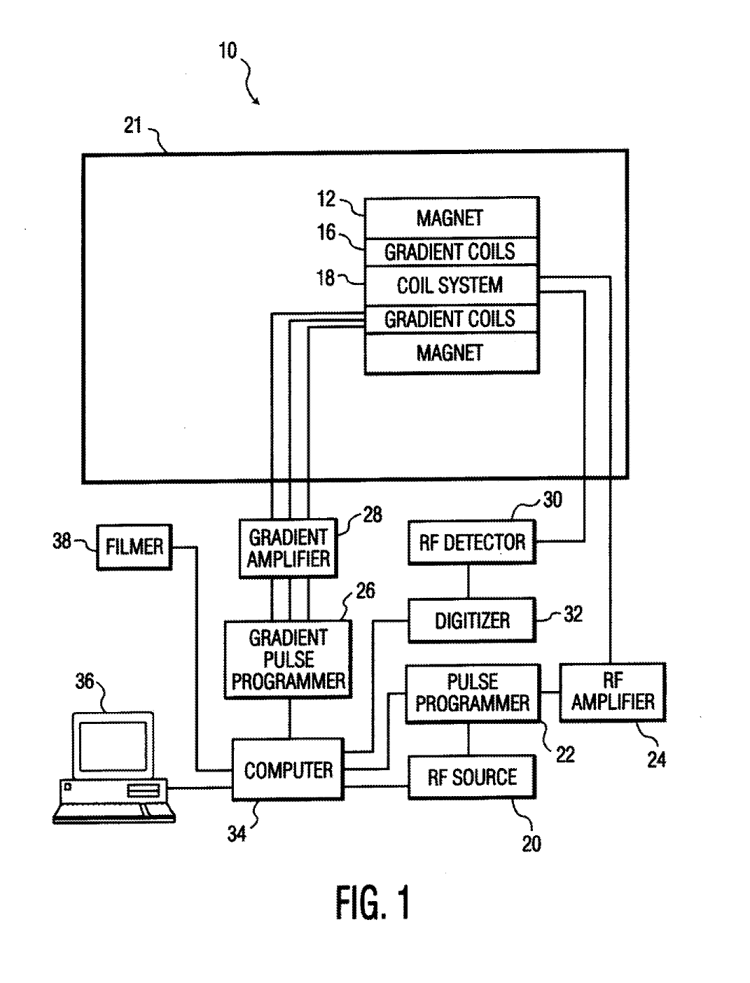

With reference to FIG. 1, an exemplary MR scanner 10 includes a main magnet 12 which produces a substantially homogeneous, temporally constant main magnetic field B₀ in an examination region. Depending on the desired main magnetic field strength and the requirements of a particular application, various magnet technologies (e.g., superconducting, resistive, or permanent magnet technologies) and physical magnet configurations (e.g., solenoidal or open magnet configurations) have been implemented. A support (not shown) can be used to support a human or animal patient or other object being examined in the examination region.

Disposed in the bore of the magnet 12 is a gradient coil 16. The gradient coil 16 has included x, y, and/or z-gradient coils, which generate time varying gradient magnetic fields along mutually orthogonal x, y, and z-axes. A coil system 18 includes an RF transmit coil that produces radio frequency signals which excite hydrogen or other magnetic resonant active nuclei in the object. The RF coil 18 also includes an RF receive coil that is located near a region of interest of the object and receives magnetic resonance signals generated by the excited nuclei. Examples of receive coils include surface coils, bird cage coils, Helmholtz pair coils, and/or other coils. While the transmit and receive coils are depicted as a combined coil, separate transmit and receives may alternatively be employed. The magnet 12, the gradient coils 16, and the RF coils 18 are typically located in a magnetically RF shielded enclosure 21.

An RF source 20 generates an RF signal having a desired frequency (e.g., the Larmor frequency of the MR active nuclei under investigation), a pulse programmer 22 shapes the RF signals, and an RF amplifier 24 amplifies the shaped signals to the levels required by the transmit coil 18 for exciting nuclei in the object. A gradient pulse programmer 26 establishes the shape and amplitude of the desired time varying magnetic fields, and a gradient amplifier 28 amplifies these signals to the levels required by the respective x, y, and z gradient coils 16. An RF detector 30 receives and amplifies the signals generated by the RF receive coil. The signals are, in turn, converted to digital form by a digitizer 32.

One or more computers 34 associated with the scanner 10 coordinate the operation of the gradient and RF systems, for example to generate desired pulse sequences. The signals generated by the digitizer 32 are further processed to generate volumetric data indicative of the object. An operator console 36 includes human perceptible input and output devices such as a keyboard, mouse, and display or monitor. The console 36 allows the operator to interact with the scanner, for example by selecting desired pulse sequences and other desired examination protocols, initiating and terminating scans, and viewing and otherwise manipulating the volumetric data. A filmer or other hard copy device 38 may be used to provide images of the volumetric data.

The RF receive coil of the coil system 18 may include conventional materials such as oxygen free copper or HTS. Alternatively, the RF receive coil may include other materials. For example, the RF receive coil may include a material with a resistivity that is less than that of oxygen free copper, which may improve performance, and/or that does not vary as much with temperature, unlike HTS, and thus there is no specific reason to cool it. An example of such a material is graphene, which is an allotrope of carbon, whose structure is one-atom-thick planar sheets of sp²-bonded carbon atoms that are densely packed in a honeycomb crystal lattice. Graphene coils can be used for both pre-clinical and clinical applications. Although, in the above, the graphene coil is described in connection with an MR scanner, it is to be understood that a graphene coil can also be utilized in a nuclear magnetic resonance (NMR) spectroscopy system, and/or other MR system.

A method includes generating a main magnetic field, via a main magnet, in an examination region. The method further includes generating, via a gradient coil, a time varying gradient magnetic fields along mutually orthogonal x, y, and/or z-axes. The method further includes producing, via an RF transmit coil, a radio frequency signal that excites magnetic resonance in magnetically active nuclei disposed in the examination region. The method further includes receiving, via an RF receive coil, magnetic resonance signals generated by the magnetically active nuclei and generating an electrical signal indicative thereof. In one instance, the RF receive coil includes graphene. The method further includes generating one or more images based on the electrical signal.

In another embodiment, a high resolution (HR) nuclear magnetic resonance (NMR) device includes a receiver configured to receive a radio frequency (RF) NMR signal. In one instance, the receiver is comprised of grapheme. This may reduce or mitigate disturbances, induced by the material of the receiver, of the electromagnetic environment of the sample being examined, relative to devices in which the receiver is comprised of one or more other materials.

In the foregoing detailed description of the preferred embodiments, reference has been made to the accompanying drawing which forms a part hereof, and in which is shown by way of illustration specific preferred embodiments in which the invention may be practiced. These embodiments are described in sufficient detail to enable those skilled in the art to practice the invention, and it is understood that other embodiments may be utilized and that logical electrical, mechanical, structural, and chemical changes may be made without departing from the spirit or scope of the invention.

What is claimed is:

1. An MR coil, comprising:
an MR RF receive coil comprising graphene.

2. An MRI imaging system, comprising:
a main magnet that generates a main magnetic field in an examination region;
a gradient coil that generates a time varying gradient magnetic field along mutually orthogonal x, y, and/or z-axes;
an RF transmit coil that produces radio frequency signals that excite magnetic resonance in magnetically active nuclei disposed in the examination region; and
an RF receive coil that receives magnetic resonance signals generated by the magnetically active nuclei and generates an electrical signal indicative thereof, wherein the RF receive coil includes graphene.

3. An NMR apparatus, comprising:
an MR receive coil comprising graphene.

4. An MR device, comprising:
an MR coil formed from a material with a resistivity that is less than that of oxygen free copper and that does not vary much with temperature relative to HTS.
